(19) United States
(12) Patent Application Publication
(10) Pub. No.: US 2022/0085336 A1
(43) Pub. Date: Mar. 17, 2022

(54) Organic Light Emitting Diode Employing Low-Refractive Capping Layer For Improving Light Efficiency

(71) Applicant: P&H TECH Co., Ltd, Gyeonggi-do (KR)

(72) Inventors: Seo-Yong HYUN, Gyeonggi-do (KR); Seok-Keun YOON, Gyeonggi-do (KR); Do Yeol YOON, Seoul (KR); Eunji KO, Gyeonggi-do (KR)

(73) Assignee: P&H TECH Co., Ltd, Gyeonggi-do (KR)

(21) Appl. No.: 17/470,389

(22) Filed: Sep. 9, 2021

(30) Foreign Application Priority Data
Sep. 17, 2020 (KR) 10-2020-0119748

(51) Int. Cl. H01L 51/52

(52) U.S. Cl. CPC H01L 51/5275; H01L 2251/558

(57) ABSTRACT

The present invention relates to an organic light emitting diode which includes a capping layer with a low refractive index to improve light extraction efficiency, thereby reducing a driving voltage, improving power efficiency, and improving current efficiency.

### CROSS-REFERENCE TO RELATED APPLICATIONS

This application claims priority to and the benefit of Korean Patent Application No. 10-2020-0119748 filed in the Korean Intellectual Property Office on Sep. 17, 2020, the entire contents of which are incorporated herein by reference.

### TECHNICAL FIELD

The present invention relates to an organic light emitting diode, and more particularly, to an organic light emitting diode which includes a capping layer with a low refractive index to improve light extraction efficiency, thereby further reducing driving voltage and improving current efficiency.

### BACKGROUND ART

An organic light emitting diode is a self-emitting diode, and has a wide viewing angle, excellent contrast, fast response, and excellent luminance, driving voltage, and response speed characteristics, and has an advantage in having a possibility of polychrome.

According to the driving and light-emitting principle of the organic light emitting diode, when a voltage is applied between an anode and a cathode, holes injected from the anode move to a light emitting layer through a hole transport layer, and electrons injected from the cathode move to the light emitting layer through the electron transport layer, and carriers, such as the holes and the electrons, are recombined in the light emitting layer region to generate exiton. Light is generated while the exitons change from an excited state to a ground state.

Light efficiency of the organic light emitting diode may be typically divided into internal quantum efficiency and external quantum efficiency, and the internal quantum efficiency is related to how efficiently exitons are generated and light conversion is performed in the organic layers, such as the hole transport layer, the light emitting layer, and the electron transport layer, interposed between the anode and the cathode, and the external quantum efficiency refers to efficiency (internal quantum efficiency×light extraction efficiency) at which light generated in the organic layer is extracted to the outside of the organic light emitting diode, and even though high light conversion efficiency is achieved in the organic layer within the diode, if the external quantum efficiency according to the light extraction efficiency (light coupling efficiency) is low, general light efficiency of the organic light emitting diode is inevitably reduced.

### SUMMARY OF THE INVENTION

Accordingly, the present invention has been made in an effect to provide an organic light emitting diode including a capping layer which is capable of further improving light extraction efficiency of the organic light emitting diode.

In order to solve the foregoing object, there is disclosed an organic light emitting diode, including: a substrate: an anode; a cathode, a multi-layer functional layer stacked between the anode and the cathode; and a capping layer stacked on a top of the cathode.

The multi-layer functional layer includes a hole injection layer, a hole transport layer, an electron blocking layer, a light emitting layer, a hole blocking layer, an electron transport layer, and an electron injection layer.

In the organic light emitting diode according to the present invention, the capping layer stacked on the top of the cathode (i) does not have light absorption in a visible light region and (ii) has a refractive index satisfying Equation 1 below.

n(λ=430 nm)−n(λ=480 nm)<0.05 [Equation 1]

In Equation 1, n(λ=X nm) represents a refractive index at a wavelength X nm.

(iii) A light absorption coefficient at the wavelength of 430 nm to 500 nm is equal to or smaller than 0.1.

(iv) The capping layer has a band gap of 3 to 4 eV.

(V) The capping layer absorbs UV at a wavelength less than 470 nm, and a maximum absorption range of UV absorbance is at a wavelength of 280 nm to 330 nm.

(vi) When a thickness of a thin film of the capping layer is 40 to 150 nm, and a thickness of the thin film is 100 nm, the capping layer has a refractive index of 1.3 to 1.8, and preferably, has a refractive index of 1.4 to 1.6.

In the organic light emitting diode according to the present invention, the light emitting layer in the multi-layer functional layer includes a blue light emitting layer, a red light emitting layer, and a green light emitting layer, and a peak wavelength of a Photoluminescence (PL) spectrum of the blue light emitting layer is 430 nm to 500 nm.

In the organic light emitting diode according to the present invention, blue, red, and green pixels are disposed in parallel on the substrate, and the capping layer is commonly provided in the blue, red, and green pixels.

In the organic light emitting diode according to the present invention, light transmittance of the cathode is 30% or more at a wavelength of 430 nm to 500 nm.

The organic light emitting diode according to the present invention includes the capping layer which is capable of optimizing light extraction efficiency to have excellent color purity, improve light extraction efficiency to further reduce a driving voltage, and improve current efficiency, so that the organic light emitting diode according to the present invention may be utilized in various lights and display devices.

### BRIEF DESCRIPTION OF THE DRAWINGS

FIG. 1 is a cross-sectional view of an organic light emitting diode according to an exemplary embodiment of the present invention.

### DETAILED DESCRIPTION

Hereinafter, the present invention will be described in more detail.

The present invention relates to a top-emission type organic light emitting diode including: a substrate; an anode; a cathode, and a multi-layer functional layer stacked between the anode and the cathode; and a capping layer stacked on the cathode, which are sequentially provided, and has the following configurations.

In the organic light emitting diode according to the present invention, the multi-layer functional layer stacked between the anode and the cathode includes a hole injection layer, a hole transport layer, an electron blocking layer, a light emitting layer, a hole blocking layer, an electron transport layer, and an electron injection layer, and the light emitting layer includes a blue light emitting layer, a red light emitting layer, and a green light emitting layer.

In the organic light emitting diode according to the present invention, the blue light emitting layer has a peak wavelength of a Photoluminescence (PL) spectrum, that is, a peak wavelength of 430 nm to 500 nm, at which light emitting intensity is maximum, and includes a blue light emitting layer material satisfying the wavelength.

In the organic light emitting diode according to the present invention, blue, red, and green pixels are disposed in parallel on the substrate, and a light efficiency improving layer (capping layer) is commonly provided in the blue, red, and green pixels.

In the organic light emitting diode according to the present invention, the capping layer stacked on the cathode is designed to have the following characteristics.

(i) There is no light absorption in the visible light region, that is, in the region with a wavelength of 430 nm to 500 nm.

(ii) The capping layer has a low refractive index satisfying Equation 1 below.

n(λ=430 nm)−n(λ=480 nm)<0.05 [Equation 1]

In Equation 1, n(λ=X nm) represents a refractive index at a wavelength X nm.

(iii) A light absorption coefficient at the wavelength of 430 nm to 500 nm is equal to or smaller than 0.1.

(iv) The capping layer has a band gap of 3 to 4 eV.

(v) The capping layer absorbs UV at a wavelength less than 470 nm, and a maximum absorption range of UV absorbance is a wavelength of 280 nm to 330 nm.

(vi) When a thickness of a thin film of the capping layer is 40 to 150 nm, and a thickness of the thin film is 100 nm, the capping layer has a refractive index of 1.3 to 1.8, and preferably, 1.4 to 1.6.

In the organic light emitting diode according to the present invention, the cathode is designed so that light transmittance is 30% or more at a wavelength of 430 nm to 500 nm.

The organic light emitting diode according to the present invention may be manufactured by using a manufacturing method and material of a general diode, except for having the capping layer, the light emitting layer, and the cathode with the foregoing characteristic conditions.

The multi-layer functional layer provided in the organic light emitting diode according to the present invention is the multi-layer structure in which two or more organic layers are stacked, and for example, the multi-layer functional layer may have the structure including the hole injection layer, the hole transport layer, the electron blocking layer, the light emitting layer, the hole blocking layer, the electron transport layer, the electron injection layer, and the like, and the multi-layer functional layer is not limited thereto, and may also include less or more organic layers.

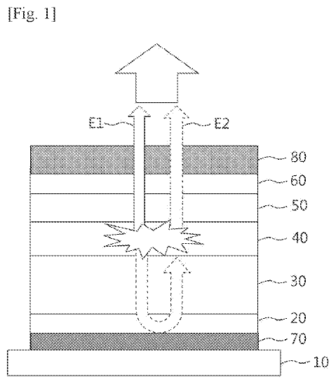

FIG. 1 is a cross-sectional view of an organic light emitting diode according to an exemplary embodiment of the present invention, and the organic light emitting diode includes a substrate 10; an anode 20; a multi-layer functional layer (a hole injection layer and hole transport layer 30, a light emitting layer 40, an electron injection layer and electron transport layer 50); a cathode 60, and a capping layer 80, and the capping layer may be formed on a top of the cathode (top-emission type).

The capping layer 80 satisfying the characteristic condition according to the exemplary embodiment of the present invention is formed on a top of the cathode 60 (top emission), the light formed in the light emitting layer 40 is emitted toward the cathode (E1), and the light formed in the light emitting layer 40 is additionally emitted toward the cathode through the reflective layer 70 formed at the side of the anode 20 (E2), and in this case, light extraction is improved while the emitted light passes through the capping layer according to the present invention, thereby improving light efficiency to further reduce a driving voltage of the diode and improving current efficiency.

Hereinafter, an exemplary embodiment of the organic light emitting diode according to the present invention will be described in more detail.

The organic light emitting diode according to the present invention may be manufactured by forming an anode by depositing a metal, a metal oxide having conductivity, or an alloy thereof on a substrate by using a Physical Vapor Deposition (PVD) method, such as sputtering or e-beam evaporation, forming a multi-layer functional layer including a hole injection layer, a hole transport layer, a light emitting laver, an electron transport layer, and the like is formed on the anode, and then depositing a material usable as a cathode on the multi-layer functional layer, and providing a capping layer.

In addition to the foregoing method, the organic light emitting diode may also be manufactured by sequentially depositing a multi-layer functional layer and a cathode material from an anode material on a substrate. The multi-layer functional layer may have a multi-layer structure including a hole injection layer, a hole transport layer, a light emitting layer, an electron transport layer, and the like. Further, the multi-layer functional layer may be manufactured in a smaller number of layers by a solvent process, for example, spin coating, dip coating, doctor blading, screen printing, inkjet printing, or a thermal transfer method, not the deposition method, by using various polymer materials.

Preferably, the anode material has a high work function for easy injection of holes into the organic layers. Specific examples of anode materials suitable for use in the present invention include, but are not limited to: metals such as vanadium, chromium, copper, zinc, and gold and alloys thereof, metal oxides such as zinc oxide, indium oxide, indium thin oxide (ITO), and indium zinc oxide (IZO); combinations of metals and oxides such as ZnO:Al and SnO2:Sb; and electrically conductive polymers such as poly(3-methylthiophene), poly[3,4-(ethylene-1,2-dioxy)thiophene] (PEDT), polypyrrole, and polyaniline.

The cathode material is preferably a material having a small work function to facilitate electron injection into the organic layer, and in the organic light emitting diode according to the present invention, in order to extract light in a front direction of the diode, light transmittance of the cathode material is preferably 30% or more at a wavelength of 430 nm to 500 nm, and is preferably transparent/translucent.

Specific examples of the cathode include metals, such as magnesium, calcium, sodium, potassium, titanium, indium, yttrium, lithium, gadolinium, aluminum, silver, tin, and lead or an alloy thereof, and a multi-layer structure material, such as LiF/Al or LiO₂/Al, but the cathode is not limited thereto, and it is preferable that the cathode has a thickness of 20 nm or less in order to achieve the foregoing light transmittance of 30% or more.

The hole injecting material is preferably a material that can receive holes injected from the anode at low voltage. The highest occupied molecular orbital (HOMO) of the hole injecting material is preferably between the work function of the anode material and the HOMO of the adjacent organic layer material. Specific examples of suitable hole injecting materials include, but are not limited to, metal porphyrin, oligothiophene, arylamine-based organic materials, hexanitrile hexaazatriphenylene, quinacridone-based organic materials, perylene-based organic materials, anthraquinone, polyaniline, and polythiophene-based conductive polymers.

The hole transport material is a material that can receive holes transported from the anode or the hole injecting layer and can transfer the holes to the light emitting layer. A material with high hole mobility is suitable as the hole transport material. Specific examples of suitable hole transport materials include arylamine-based organic materials, conductive polymers, and block copolymers consisting of conjugated and non-conjugated segments. The use of the organic electroluminescent compound according to the present invention ensures further improved low-voltage driving characteristics, high luminous efficiency, and excellent life characteristics of the device.

The light emitting material is a material that can receive and recombine holes from the hole transport layer and electrons from the electron transport layer to emit light in the visible range. A material with high quantum efficiency for fluorescence and phosphorescence is preferred as the light emitting material. Specific examples of suitable light emitting materials include, but are not limited to, 8-hydroxyquinoline aluminum complex (Alq₃), carbazole-based compounds, dimerized styryl compounds, BAlq, 10-hydroxybenzoquinoline-metal compounds, benzoxazole-based compounds, benzthiazole-based compounds, and benzimidazole-based compounds, poly(p-phenylenevinylene) (PPV)-based polymers, spiro compounds, polyfluorene, and rubrene.

However, in the blue light emitting layer in the organic light emitting diode according to the present invention, a blue light emitting layer material is designed so that a peak wavelength of the PL spectrum is 430 nm to 500 nm.

The electron transport material is a material that can receive electrons injected from the cathode and can transfer the electrons to the light emitting layer. A material with high electron mobility is suitable as the electron transport material. Specific examples of suitable electron transport materials include, but are not limited to, 8-hydroxyquinoline Al complex (Alq₃), Alq₃ complexes, organic radical compounds, hydroxyflavone-metal complexes.

Hereinafter, in the organic light emitting diode according to the present invention, the present invention will be described in more detail based on the Example using the capping layer material satisfying the characteristic condition.

### EXAMPLE

In the Experimental Example according to the present invention, quartz glass having a size of 25 mm×25 mm was washed. Then, the glass was mounted to a vacuum chamber, and when a base pressure is 1×10⁻⁶ torr or larger, an optical characteristic was measured by depositing each of a capping layer material compound of the organic light emitting diode according to the present invention and a comparative compound on a glass substrate.

### Diode Examples 1 and 2

A refractive index was measured by depositing each of capping layer Compounds 1 and 2 implementing the organic light emitting diode according to the present invention on the glass substrate by 60 to 100 nm.

Quartz glass/organic material (60-100 nm)

### Comparative Example 1

In Comparative Example 1, the optical characteristic was measured by manufacturing the organic light emitting diode in the same manner, except that α-NPB was used instead of the capping layer compounds 1 and 2 according to the present invention.

### Experimental Example 1: Optical Characteristics of Experimental Examples 1 and 2

A refractive index of the substrate manufactured according to the Example was measured by using Ellipsometry (Elli-SE). A refractive index was measured in the wavelength region of each of blue (450 nm), green (520 nm), and red (630 nm), and a result thereof is represented in Table 1 below.

A difference in the refractive indexes between the wavelength regions of the colors, that is, a difference ΔB-G between a refractive index at a wavelength (450 nm) of blue and a refractive index at a wavelength (520 nm) of green, a difference ΔG-R between a refractive index at a wavelength (520 nm) of green and a refractive index at a wavelength (630 nm) of red, and a difference ΔB-R between a refractive index at a wavelength (450 nm) of blue and a refractive index at a wavelength (630 nm) of red were calculated, and the calculation result is represented in Table 2 below.

Last, the refractive indexes at the wavelengths of 430 nm and 480 nm, and the refractive index difference values between the wavelengths of 430 nm and 480 nm are represented in Table 3 below.

TABLE 1

| | | | Refractive index |
|---|---|---|---|
| Division | Blue (450 nm) | Green (520 nm) | Red (630 nm) |
| Example 1 | 1.56 | 1.53 | 1.51 |
| (Compund 1) | | | |
| Example 2 | 1.62 | 1.60 | 1.57 |
| (Compund 2) | | | |
| Comparative | 1.92 | 1.84 | 1.78 |
| Example (α-NPB) | | | |

TABLE 2

| | Refractive index difference | | |
|---|---|---|---|
| Division | Δ_{B-G} | Δ_{G-R} | Δ_{B-R} |
| Example 1 | 0.03 | 0.02 | 0.05 |
| (Compund 1) | | | |
| Example 2 | 0.02 | 0.03 | 0.05 |
| (Compund 2) | | | |
| Comparative | 0.09 | 0.06 | 0.14 |
| Example (α-NPB) | | | |

TABLE 3

| | Refractive index | | |
|---|---|---|---|
| | | | Δ(430 nm-480 |
| Division | n (430 nm) | n (480 nm) | nm) |
| Example 1 | 1.57 | 1.54 | 0.03 |
| (Compund 1) | | | |
| Example 2 | 1.63 | 1.61 | 0.02 |
| (Compund 2) | | | |
| Comparative | 1.94 | 1.87 | 0.07 |
| Example (α-NPB) | | | |

The refractive index values of the capping layer of the organic light emitting diode according to the present invention at the wavelength bands 450, 520, and 630 nm are significantly lower than the refractive index value of the Comparative Example (α-NPB), and all of the difference values (ΔB-G, ΔG-R, and ΔB-R) of the refractive indexes in the wavelength regions of the colors are 0.05 or less.

The values of the refractive index difference (430 to 480 nm) in the wavelength of blue are 0.03 and 0.02, respectively, and satisfy the value of 0.05 or less. The values are significantly lower than 0.09, 0.06, and 0.14, which are the differences in the refractive index (ΔB-G, ΔG-R, and ΔB-R) of α-NPB.

The low refractive index value and the small refractive index difference value in each wavelength region solve the problems of light extraction efficiency degradation, so that when the capping layer is provided like the organic light emitting diode according to the present invention, it is possible to expect the efficiency optimization of the diode.

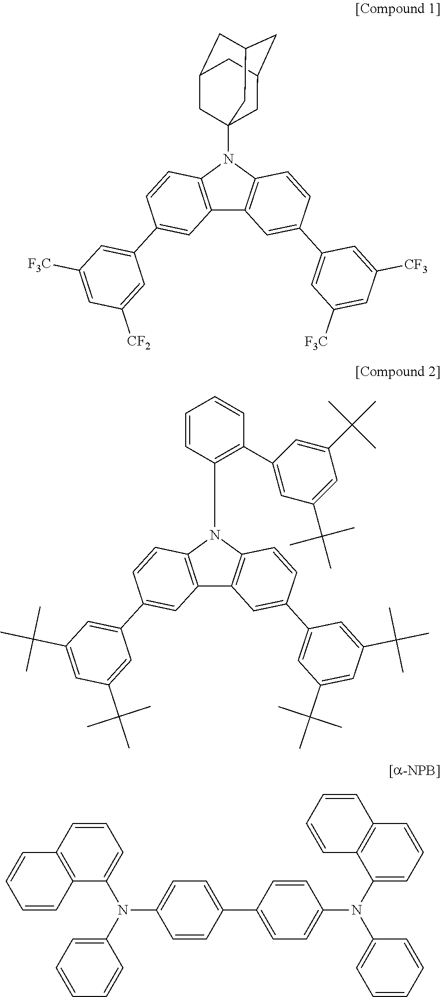

### Diode Examples 3 and 4

Organic light emitting diodes having the following structure were manufactured by providing the capping layer satisfying the characteristic condition according to the present invention, and a light emission characteristic including light emission efficiency was measured.

Ag/ITO/hole injection layer (HAT-CN, 5 nm)/hole transport layer (TAPC, 100 nm)/electron blocking layer (TCTA, 10 nm)/light emitting layer (20 nm)/electron transport layer (201:Liq, 30 nm)/LiF (1 nm)/Mg:Ag (15 mu)/capping layer (70 nm)

HAT-CN was deposited in a thickness of 5 nm to form a hole injection layer in an ITO transparent electrode including Ag on a glass substrate, and then TAPC was deposited in a thickness of 100 nm in order to form a hole transport layer. TCTA was deposited in a thickness of 10 nm to form an electron blocking layer. Further, a host compound and a dopant compound were co-deposited on a light emission layer by using BH1 and BD1, respectively, in a thickness of 20 nm. In addition, an electron transport layer was deposited a thickness of 30 nm and 1 nm by using [201] compound (Liq 50% doping) and LiF, respectively. Subsequently. Mg:Ag was deposited in a ratio of 1:9 in a thickness of 15 nm. Then, a capping layer was deposited in a thickness of 70 nm by using compounds 1 and 2 of the Example to manufacture the organic light emitting diode.

### Comparative Example 2

An organic light emitting diode for Comparative Example 2 of the diode was manufactured in the same manner as that of the Example, except that α-NPB was used in the capping layer.

### Experimental Example 2: Light Emission Characteristics of Diode Examples 3 and 4

For the organic light emitting diodes manufactured according to the Example and the Comparative Example, a driving voltage, current efficiency, and color coordinates were measured by using a source meter (Model 237, Keithley) and a luminance meter (PR-650, Photo Research), and a result value based on 1,000 nit is represented in Table 4 below.

| | | | Light | | |
|---|---|---|---|---|---|
| | | Driving | emitting | | Light |
| | Capping | voltage | efficiency | Power | extraction |
| Division | layer | (v) | (cd/A) | efficiency | efficiency |
| Example 3 | Compound 1 | 3.6 | 8.8 | 7.7 | 1.13 |
| Example 4 | Compound 2 | 3.7 | 8.6 | 7.3 | 1.10 |
| Comparative | α-NPB | 4.3 | 7.8 | 5.7 | 1.00 |
| Example 2 | | | | | |

Reviewing the result represented in Table 4, it can be seen that in the case where the capping layer having a low refractive index is provided in the diode like the organic light emitting diode according to the present invention, light extraction efficiency is improved 10% or more compared to the diode in the related art (Comparative Example 2). Further, it can be seen that the driving voltage is decreased and current efficiency is improved.

This is because the refractive indexes and the difference values (ΔB-G, ΔG-R, and ΔB-R) of the refractive indexes in the wavelength regions of the respective colors are small, and through this, the light extraction efficiency is improved, so that the diode characteristic may be further improved.

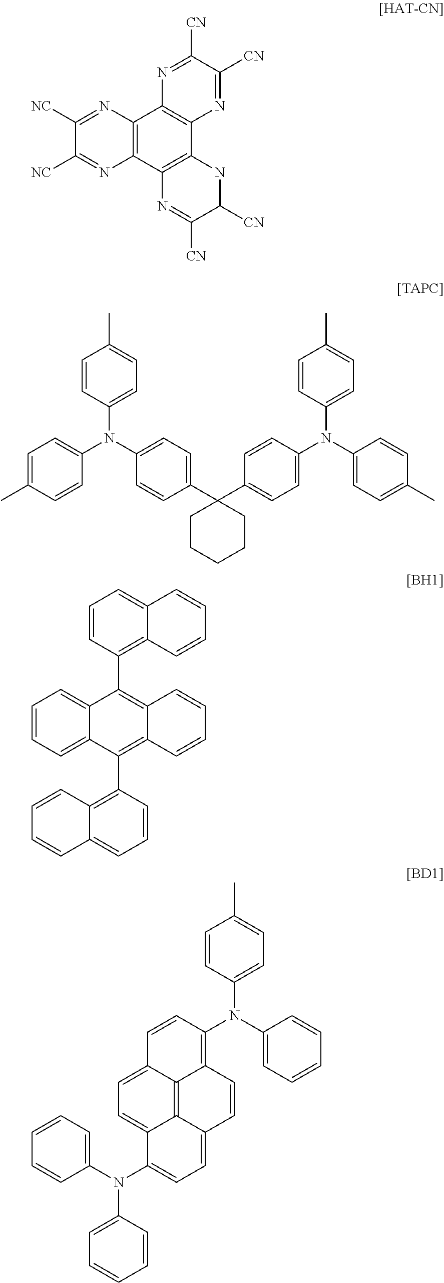

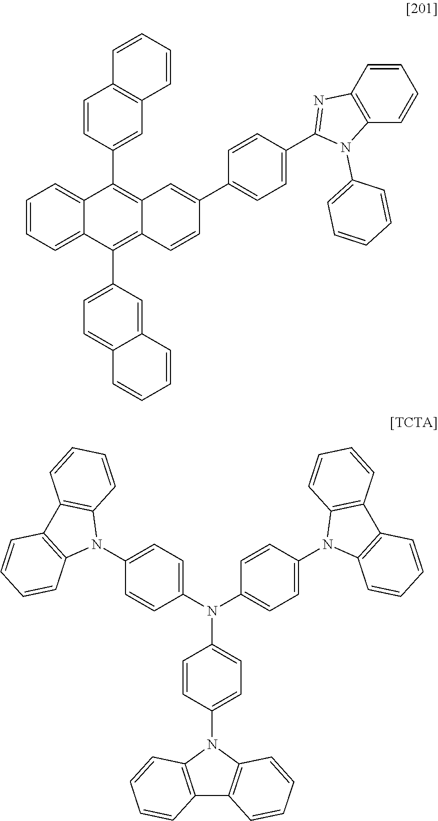 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

What is claimed is:

1. An organic light emitting diode, comprising:
a substrate;
an anode;
a cathode;
a multi-layer functional layer stacked between the anode and the cathode; and
a capping layer stacked on a top of the cathode,
wherein the multi-layer functional layer includes a hole injection layer, a hole transport layer, an electron blocking layer, a light emitting layer, a hole blocking layer, an electron transport layer, and an electron injection layer, and
the capping layer stacked on the top of the cathode does not have light absorption in a visible light region, has a refractive index satisfying Equation 1 below, and a light absorption coefficient at a wavelength of 450 nm to 500 nm is 0.1 or less,
n(λ=430 nm)−n(λ=480 nm)<0.05 [Equation 1]
in Equation 1, n(λ=X nm) represents a refractive index at a wavelength X nm.

2. The organic light emitting diode of claim 1, wherein a thickness of the capping layer is 150 nm or less.

3. The organic light emitting diode of claim 1, wherein a peak wavelength of a Photoluminescence (PL) spectrum of the light emitting layer is 430 nm to 500 nm.

4. The organic light emitting diode of claim 1, wherein light transmittance of the cathode is 30% or more at a wavelength of 430 nm to 500 nm.

5. The organic light emitting diode of claim 1, wherein the capping layer has a band gap of 3 to 4 eV.

6. The organic light emitting diode of claim 1, wherein the capping layer absorbs UV at a wavelength of less than 470 nm.

7. The organic light emitting diode of claim 1, wherein a maximum absorption range of UV absorbance of the capping layer is a wavelength of 280 to 330 nm.

8. The organic light emitting diode of claim 1, wherein when a thickness of the capping layer is 100 nm, the capping layer has a refractive index of 1.3 to 1.8.

9. The organic light emitting diode of claim 1, wherein when a thickness of the capping layer is 100 nm, the capping layer has a refractive index of 1.4 to 1.6.

10. The organic light emitting diode of claim 1, wherein the capping layer has a thickness of 40 to 150 nm.

11. The organic light emitting diode of claim 1, wherein the capping layer has a thickness of 40 to 70 nm.

12. The organic light emitting diode of claim 1, wherein the light emitting layer is a blue light emitting layer, and the multi-layer functional layer further includes a red light emitting layer and a green light emitting layer.

13. The organic light emitting diode of claim 1, wherein blue, red, and green pixels are disposed in parallel on the substrate, and the capping layer is commonly provided in the blue pixel, the red pixel, and the green pixel.
